(19) United States
(12) Patent Application Publication
(10) Pub. No.: US 2013/0239889 A1
(43) Pub. Date: Sep. 19, 2013

(54) VALVE PURGE ASSEMBLY FOR SEMICONDUCTOR MANUFACTURING TOOLS

(71) Applicants: Ming Huei LIEN, New Taipei City (TW); Chia-Ho CHEN, Zhubei City (TW); Shu-Fen WU, Yilan City (TW); Chih-Tsung LEE, Hsinchu City (TW); You-Hua CHOU, Taipei City (TW)

(72) Inventors: Ming Huei LIEN, New Taipei City (TW); Chia-Ho CHEN, Zhubei City (TW); Shu-Fen WU, Yilan City (TW); Chih-Tsung LEE, Hsinchu City (TW); You-Hua CHOU, Taipei City (TW)

(73) Assignee: TAIWAN SEMICONDUCTOR MANUFACTURING CO., LTD., Hsin-Chu (TW)

(21) Appl. No.: 13/419,835

(22) Filed: Mar. 14, 2012

(51) Int. Cl. C23C 16/00; F24F 7/00

(52) U.S. Cl. 118/715; 454/237

(57) ABSTRACT

A semiconductor manufacturing tool and method for operating the tool are provided. The semiconductor manufacturing tool includes a process chamber in which plasma operations or ion etching operations are carried out and a valve assembly for opening and closing a valve that provides for loading and unloading substrates into and out of, the semiconductor manufacturing tool. While a processing operation is being carried out in the chamber, a valve assembly purge operation also takes place. The valve assembly purge operation involves inert gases being directed to the valve assembly area to prevent the buildup of particles and contaminating films in the valve assembly. Because the valve assembly is maintained in a clean condition, particle contamination is reduced or eliminated.

### TECHNICAL FIELD

The disclosure relates to semiconductor manufacturing equipment. More particularly, the disclosure relates to a method and apparatus for purging a valve assembly while operating a plasma tool in semiconductor manufacturing.

### BACKGROUND

Various types of semiconductor manufacturing tools are used to process semiconductor substrates, i.e. “wafers” during the manufacturing of integrated circuits (IC's). For example, chemical vapor deposition (CVD) systems are used to deposit insulating and non-insulating layers on or over a wafer, atomic layer deposition (ALD) systems are used to deposit insulating and non-insulating materials on or over a wafer, plasma etch systems are used to etch a wafer or a layer formed over the wafer, and physical vapor deposition or “sputter” systems are used to physically deposit conductive layers on or over a wafer. These various processes are usually performed within sealed processing chambers so that the processing conditions such as pressure can be controlled. In many cases a plasma is generated and utilized in the processing operation. The sealed processing chambers must be regularly cleaned between processing operations to maintain cleanliness and the sealed processing chambers also undergo conditioning operations to condition the chamber to be used for different operations. Cleaning and conditioning processes are carried out in a manner similar to manufacturing process operations, i.e. a plasma is generated and used along with gases which serve as cleaning or conditioning gases.

A common way of loading a wafer into a processing chamber and then subsequently unloading it is to provide a “slit valve” in a wall of the processing chamber. An elongated, usually horizontal, aperture is formed in the wall. The aperture is sufficiently wide and high to permit the passage of a semiconductor wafer supported by the blade of a robotic wafer handling arm or other loading mechanism, and is surrounded by a valve seat. An elongated valve closure selectably engages the seat to close the aperture or disengages from the seat to open the aperture.

When the slit valve is closed, a gas-tight seal is required in order to isolate the chamber from external influences. This usually requires an elastomeric gasket or seal, such as an O-ring seal, disposed between the valve seat and the closure.

It is very important to minimize sources of contamination in semiconductor manufacturing equipment. Even very small particles on the order of 0.2 microns can damage or even destroy an IC device being created on a semiconductor wafer. A common problem is that the elastomeric material of the O-ring or gasket can be degraded and attacked by the processing gasses used to perform processing operations, the cleaning gasses used to clean the process chamber or the conditioning gases used to condition the process chamber. When the O-ring or gasket becomes degraded, particle contamination is generated. The pressure differential that may be still present when the valve is opened, can exacerbate the disengagement of particles from the O-rings. The contaminating particles become deposited on the wafers that are loaded through the aperture and can damage or even destroy the integrated circuits formed on the wafers.

### BRIEF DESCRIPTION OF THE DRAWING

The present disclosure is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIG. 1 is a cross-sectional side view of a semiconductor manufacturing processing chamber according to an embodiment of the disclosure;

FIG. 2 is an expanded cross-sectional view of a valve assembly according to the disclosure; and

FIG. 3 is a flowchart illustrating a method of the disclosure.

### DETAILED DESCRIPTION

The disclosure provides an apparatus for manufacturing semiconductor devices. Such apparatuses are also commonly referred to as “tools”. The apparatus includes a purge assembly that purges a value assembly including a loading aperture of a process chamber while the process chamber is being used to carry out plasma processing operations. The disclosure also provides a method for operating the apparatus to produce semiconductor devices such as integrated circuits.

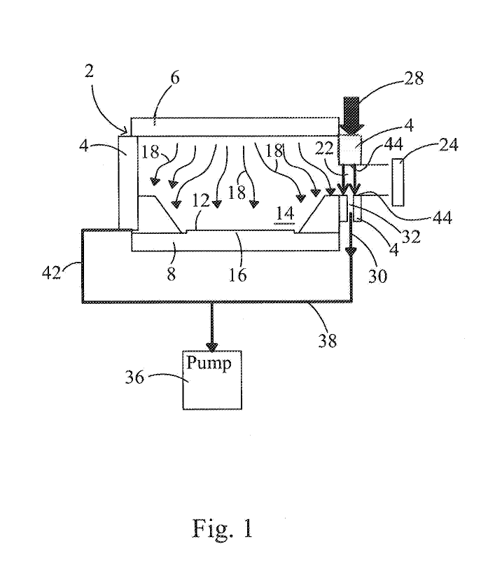

FIG. 1 is a side view showing a cross-section of an embodiment of a process chamber according to the disclosure. Process chamber 2 is one process chamber in a large semiconductor manufacturing tool that includes multiple process chambers, in one embodiment. In other embodiments, process chamber 2 represents the process chamber in a one-chamber semiconductor manufacturing tool. Process chamber 2 includes sidewalls 4, top 6 and bottom 8. In many embodiments, process chamber 2 is a process chamber in which a plasma is generated and utilized for processing substrates. In one embodiment, process chamber 2 is used for atomic layer deposition (ALD). In another embodiment, process chamber 2 is used for chemical vapor deposition (CVD). In another embodiment, process chamber 2 is used for physical vapor deposition (PVD) such as sputtering. In yet another embodiment, process chamber 2 is used for plasma etching such as RF etching. In other embodiments, process chamber 2 is used for other plasma or reactive ion etch processing operations. In some embodiments, process chamber 2 is used in more than one of the previous capacities.

Process chamber 2 is used to process semiconductor substrates such as wafer 12 shown in interior 14 of process chamber 2, and to carry out various processing operations upon wafer 12. Wafer 12 represents any of various types and sizes of semiconductor substrates. Wafer 12 rests upon stage 16 in FIG. 1. Stage 16 may be a chuck or other suitable substrate holding member. Gases or other atoms, molecules or ions are delivered to process chamber 2 and directed toward wafer 12 as indicated by arrows 18. Process chamber 2 includes or is coupled to a plasma generation unit in one embodiment. The plasma generator unit is an RF plasma generation unit in one embodiment. In other embodiments, process chamber 2 includes one or more electrode arrangements for generating plasmas or ionizing gasses and directing the ionized gases toward wafer 12 as indicated by arrows 18. In other embodiments, process chamber 2 includes various gas delivery means (not shown) including gas lines, valves and inlet ports for delivering various process, cleaning or conditioning gasses to process chamber 2. Process chamber 2 also includes other process control features such as valves that regulate the flow of the process gases into process chamber 2, a heater element or other temperature controlling devices that maintain a desired pressure and temperature within process chamber 2, and other features that control the processing parameters in process chamber 2, in various embodiments.

Various gases are delivered to process chamber 2 in various embodiments. Some gases may be suitable and used for the aforementioned processing operations such as carried out upon production devices. Other gases are used as cleaning gases. In one embodiment, NF₃ is used as a cleaning gas but other cleaning gases are used in other embodiments. The cleaning operations are carried out regularly to maintain a level of cleanliness within the process chamber and may be carried out at various frequencies. In one embodiment, the cleaning operation utilizes a plasma ignition that ionizes the cleaning gas to clean the exposed surfaces within process chamber 2. Conditioning operations are additionally used to condition the process chamber for various reasons including but not limited to conditioning the process chamber after being idle for a prescribed time or after the performance of maintenance work on the process chamber or when the process chamber is being converted to be used for a different processing operation. Conditioning may be carried out for other reasons in other embodiments.

During a processing, cleaning or conditioning operation, processing or cleaning or conditioning gasses are delivered to process chamber 2 by various suitable gas delivery means (not shown). A plasma is generated of the gaseous species in process chamber 2. In one embodiment, process chamber 2 may include or be coupled to a power source and an RF plasma generator unit that creates the plasma in process chamber 2. Process chamber 2 also includes a heating element in various embodiments and a pressure sensor and controller to maintain a desire pressure in various embodiments. Any of the aforementioned processing operations may be carried out upon wafer 12 as described previously. In other operations, a cleaning operation is carried out and the cleaning operation may include wafer 12 in one embodiment and in another embodiment, the cleaning operation will also clean stage 16 upon which wafer 12 rests, i.e., wafer 12 is not present. In conditioning operations, wafer 12 will generally be present but in some embodiments, wafer 12 may not be used for conditioning. At the same time the processing or cleaning or conditioning operation is being carried out, a purging operation is being carried out at the aperture through which wafer 12 is transported when process chamber 2 is being loaded or unloaded.

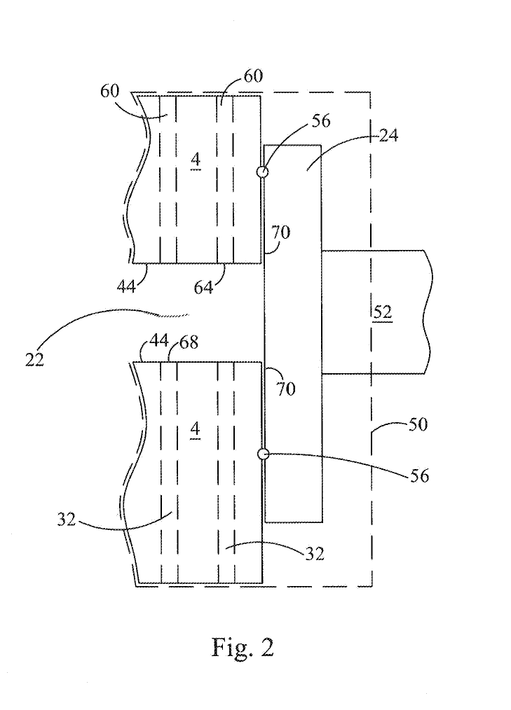

Sidewall 4 on the right hand side of FIG. 1 includes aperture 22 therethrough. Aperture 22 is a slit in some embodiments and in many embodiments will be a generally horizontal slit through which wafer 12 can be transported using a robotic loading mechanism or other loading mechanisms. Door 24 is illustrated just outside process chamber 2 in FIG. 1 and is part of a valve assembly that opens and closes by moving door 24 into and out of closed position over aperture 22. The valve assembly including door 24 is shown in more detail in FIG. 2. Door 24 is shown aligned with aperture 22 such as is the case following wafer 12 being loaded into process chamber 2 or just prior to wafer 12 being unloaded from process chamber 2. When the loading or unloading operation actually takes place, door 24 is moved to a different position to accommodate the loading or unloading of wafer 12 through aperture 22. Aperture 22 is defined and bounded by internal surfaces 44 of sidewall 4. Various pneumatic or other mechanisms are used for opening and closing door 24. Door 24 forms a detachable seal with sidewall 4 of process chamber 2, as also shown in FIG. 2.

Still referring to FIG. 1, the purge assembly includes a delivery system for delivering an inert purge gas to the valve assembly after door 24 has been closed and while a plasma operation is being carried out in process chamber 2. The delivery of the inert purge gas is shown schematically as arrow 28 in FIG. 1. The inert purge gas may be at least one of N₂, Ar and He. Other purge gases may be used in other embodiments. The purge gases are delivered to the purge assembly while process chamber 2 is being operated, i.e., carrying out a processing, cleaning or conditioning operation as described above. Exhausted purge gas is represented schematically by arrow 30. Exhausted purge gas 30 is pumped through exhaust lines 32 by pump 36 which also pumps exhaust gas 30 through exhaust line section 38. In the illustrated embodiment, pump 36 also includes exhaust line section 42 that pumps process chamber 2. In another embodiment, two separate pumps are used. Various suitable pumps such as are known or are being developed in the semiconductor manufacturing industry, can be used as pump 36.

Valve assembly 50 is shown more clearly and in more detail in FIG. 2. Valve assembly 50 includes a portion of sidewalls 4 of process chamber 2, door 24, a purge assembly, aperture 22 and valve member 52 that opens and closes door 24. Valve member 52 is coupled to any of various motors or other pneumatic or other mechanisms to move door 24 into and out of closed position. Door 24 forms a detachable seal with the valve seat. More particularly, door 24 contacts the outer surfaces of sidewalls 4 to form a detachable seal, closing aperture 22. O-ring 56 is formed of an elastomeric material such as rubber or other suitable O-ring materials. In other embodiments, other gaskets or other suitable deformable sealing members such as elastomeric materials are used. O-ring 56 is secured within a groove, trench or other receiving member formed in door 24. When door 24 is closed and a detachable seal is formed between door 24 and the valve seat, i.e. the outer surfaces of sidewalls 4, processing operations are carried out within process chamber 2 as shown in FIG. 1.

The processing operations include manufacturing operations as described above, cleaning operations and conditioning operations. While the processing operations are being carried out in process chamber 2, gases are being delivered to process chamber 2 and a plasma and/or ionized species may be present in process chamber 2. Also at this time, the processing gases are being exhausted from process chamber 2.

During the processing operation, a purging operation also takes place at valve assembly 50. Inert purge gases are delivered through delivery ports such as delivery lines 60, indicated by the dashed lines, and disposed internal to sidewalls 4. In the illustrated embodiment, inert gas delivery lines 60 terminate at gas delivery ports 64. Gas delivery ports 64 represent openings formed in internal surfaces 44 of sidewall 4. Inert gas delivery lines 60 deliver inert purging gases to valve assembly 50 at aperture 22. The gases are exhausted through exhaust lines 32 which are formed within sidewalls 4. Exhaust ports 68 lie at the intersection of exhaust lines 32 and internal surfaces 44. While a plasma processing operation is being carried out within process chamber 2, valve assembly 50 is being simultaneously purged to maintain cleanliness of valve assembly 50. This maintains the integrity of O-ring 56. It should be noted that O-ring 56 may be in closer proximity to aperture 22 in other embodiments. In one embodiment, O-ring 56 may be disposed at location 70. In another embodiment, multiple O-rings may be used, e.g. an outer one and an inner one at location 70. In another embodiment, a gasket is used to form the detachable seal between door 24 and sidewalls 4.

Various flow rates are delivered to aperture 22 and various inert gases such as N₂, Ar and He are delivered to aperture 22, and various exhaust pumping rates are used to purge valve assembly 50 in various embodiments.

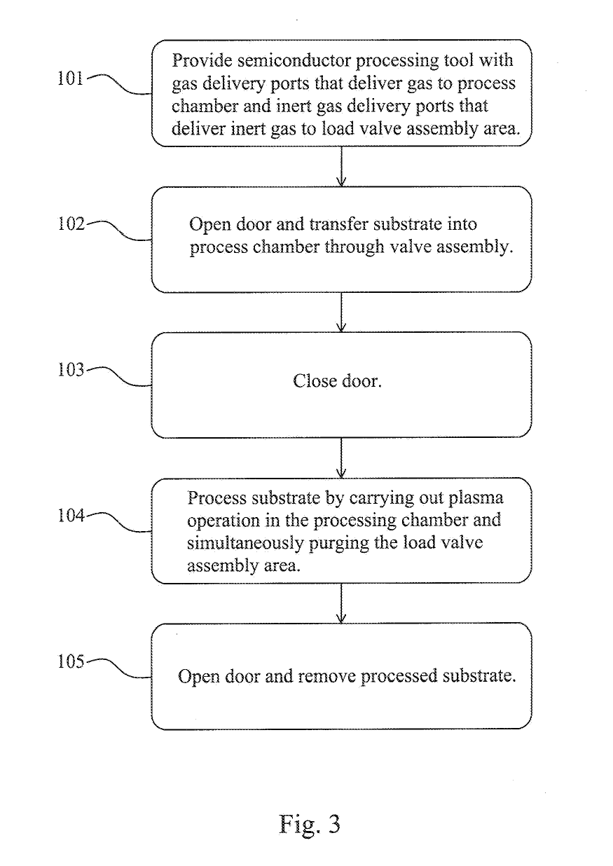

FIG. 3 is a flow chart showing a method according to the disclosure. At step 101, a semiconductor processing tool is provided. The semiconductor processing tool includes gas delivery lines and ports that deliver gas to a process chamber and inert gas delivery ports that deliver inert gas to the load valve assembly area. The semiconductor processing tool may be any of the described plasma processing tools capable of generating a plasma and/or ionizing gas in a process chamber to perform a processing operation on product wafers and to carry out cleaning and conditioning operations. Step 102 provides for opening the door to the process chamber. Various valve types are used. Step 102 also provides for transferring the substrate into the process chamber through the valve assembly. After the substrate is loaded into the process chamber, step 103 provides for closing the door. The process chamber is then readied for carrying out the processing operation. In various embodiments, the process chamber is pumped down to a sufficiently low base pressure and other checks or calibrations may be carried out prior to initiating processing. Step 104 involves processing the substrate by carrying out the plasma operation in the processing chamber and simultaneously purging the load valve assembly area. The purging is carried out as described above. After completion of the processing operation, step 105 provides for opening the door and removing the processed substrate.

Various power sources and controllers are available and are used to operate the process chamber and simultaneously carry out the purge operation for the valve assembly in various embodiments. When the processing operation in the process chamber is concluded, the purging of the valve assembly continues according to one embodiment, although it may be terminated in other embodiments. The purging of the valve assembly may continue identically or at a lower flow rate or it may be terminated when the door is opened for unloading and while the substrates are unloaded and loaded.

Since the valve assembly area was purged with inert gas during processing, the buildup of a contaminating film or contaminating particles in the valve assembly area is alleviated. Valve assembly 50, shown in the previous figures, is maintained in a clean condition and when door 24 is opened, valve assembly 50, including O-ring 56, is clean and any possible particle contamination in the valve assembly is eliminated or significantly reduced.

In one embodiment, a semiconductor manufacturing tool is provided. The semiconductor manufacturing tool comprises a process chamber with a sidewall that includes an aperture therethrough for transferring substrates therethrough. The semiconductor manufacturing tool also includes a door that covers the aperture and forms a detachable seal with the sidewall, a delivery port that delivers an inert gas to the aperture, and an exhaust port through which the inert gas is exhausted from the aperture. Also provided is a method for operating a semiconductor manufacturing apparatus. The method comprises providing a process chamber with a sidewall and an aperture therethrough, providing a door that forms a detachable seal with the sidewall to close the aperture, operating the apparatus by carrying out an operation within the process chamber, delivering an inert purge gas to the aperture during the operating, and exhausting the inert purge gas from the aperture during operating.

The preceding merely illustrates the principles of the disclosure. It will thus be appreciated that those of ordinary skill in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended claims should be construed broadly, to include other variants and embodiments of the disclosure, which may be made by those of ordinary skill in the art without departing from the scope and range of equivalents of the disclosure.

What is claimed is:

1. A semiconductor manufacturing tool comprising:
a process chamber with a wall that includes an aperture therethrough for transferring substrates therethrough;
a door that covers said aperture and forms a detachable seal with said wall;
a delivery port that delivers an inert gas to said aperture; and
an exhaust port through which said inert gas is exhausted from said aperture.

2. The semiconductor manufacturing tool as in claim 1, wherein said process chamber includes gas lines that deliver process gasses to said process chamber and a plasma generator unit for creating a plasma in said process chamber.

3. The semiconductor manufacturing tool as in claim 2, wherein said process chamber is adapted for at least one of atomic layer deposition (ALD) and chemical vapor deposition (CVD), and includes a heating element.

4. The semiconductor manufacturing tool as in claim 2, further comprising a pump coupled to said exhaust port, and a controller that controls delivery of said inert gas to said aperture while a plasma operation is being carried out in said process chamber.

5. The semiconductor manufacturing tool as in claim 2, wherein said aperture is defined and bounded by a peripheral surface internal to said wall and said exhaust port comprises a conduit within said wall that terminates in said peripheral surface.

6. The semiconductor manufacturing tool as in claim 1, wherein said process chamber comprises a plasma etching process chamber and includes an electrode arrangement that ionizes gasses and directs said ionized gasses to a substrate in said process chamber.

7. The semiconductor manufacturing tool as in claim 1, wherein said door includes an O-ring that contacts said wall and creates said detachable seal, and wherein said wall comprises a sidewall.

8. The semiconductor manufacturing tool as in claim 7, wherein said delivery port is contained within said sidewall.

9. The semiconductor manufacturing tool as in claim 1, wherein said aperture is defined and bounded by a peripheral surface internal to said wall and said delivery port comprises a gas delivery line within said wall that terminates in said peripheral surface.

10. A method for operating a semiconductor manufacturing apparatus, said method comprising:
providing a process chamber with a sidewall and an aperture therethrough;
providing a valve assembly including a door that forms a detachable seal with said sidewall to close said aperture;
operating said apparatus by carrying out an operation within said process chamber;
delivering an inert purge gas to said valve assembly during said operating; and
exhausting said inert purge gas from said valve assembly during said operating.

11. The method as in claim 10, wherein said operating includes delivering at least one process gas to said process chamber and generating at least one of a plasma and an ionized gas species in said process chamber with said door closed and said seal formed.

12. The method as in claim 11, wherein said operating further comprises heating a substrate disposed in said process chamber.

13. The method as in claim 11, wherein said operating comprises one of chemical vapor deposition (CVD) and atomic layer deposition (ALD).

14. The method as in claim 11, wherein said operating comprises plasma etching.

15. The method as in claim 10, wherein said operating comprises cleaning said process chamber by at least delivering a cleaning gas to said process chamber and generating a plasma in said process chamber.

16. The method as in claim 15, wherein said cleaning gas comprises NF₃.

17. The method as in claim 10, wherein said inert purge gas comprises at least one of N₂, Ar and He.

18. The method as in claim 10, wherein said aperture is defined and bounded by a peripheral surface interior to said sidewall, said delivering an inert purge gas comprises delivering said inert purge gas through a conduit having an opening in said peripheral surface and said exhausting said inert purge gas comprises exhausting said inert purge gas through a conduit having an opening in said peripheral surface.

19. The method as in claim 10, wherein said exhausting comprises pumping said inert gas through an exhaust line disposed within said sidewall, and further comprising further pumping processing gases from said process chamber, said pumping and said further pumping performed by a single pump.

20. The method as in claim 10, wherein said door includes an elastomeric sealing member that forms said detachable seal with said sidewall, said elastomeric sealing member comprising one of an O-ring and a gasket, and wherein said operating said apparatus takes place after closing said door.
